(19) United States
(12) Patent Application Publication
(10) Pub. No.: US 2026/0068603 A1
(43) Pub. Date: Mar. 5, 2026

(54) USING SIGNAL MINIMA IN EDDY CURRENT MONITORING

(71) Applicant: Applied Materials, Inc., Santa Clara, CA (US)

(72) Inventors: Kun Xu, Sunol, CA (US); Harry Q. Lee, Los Altos, CA (US); Jun Qian, Sunnyvale, CA (US); Patrick A. Higashi, Hacienda Heights, CA (US); Benjamin Cherian, San Jose, CA (US); Chen-Wei Chang, New Taipei City (TW)

(21) Appl. No.: 18/820,202

(22) Filed: Aug. 29, 2024

(51) Int. Cl. H01L 21/66; G01B 7/06; H01L 21/321

(52) U.S. Cl. CPC H01L 22/12; G01B 7/06

(57) ABSTRACT

During polishing of a backside conductive layer, a sensor of an in-situ eddy current monitoring system is repeatedly swept across the substrate so that each respective sweep of the sensor generates a respective signal trace that includes a sequence of signal values. For each respective signal trace, the sequence of signal values is converted to a corresponding thickness trace that includes sequence of thickness values for different locations on the substrate, thus generating a sequence of thickness traces. For each respective thickness trace in the sequence of thickness traces, a plurality of minima in the respective thickness trace are identified. A sequence of layer thickness values over time is calculated based on the plurality of minima from the respective traces in the sequence of thickness traces. Conductive vias extend through the semiconductor wafer of the substrate to electrically connect the backside conductive layer to a front-side conductive layer.

### TECHNICAL FIELD

The present disclosure relates to eddy-current monitoring during chemical mechanical polishing of substrates.

### BACKGROUND

An integrated circuit is typically formed on a substrate by the sequential deposition of conductive, semiconductive, or insulative layers on a silicon wafer. A variety of fabrication processes require planarization of a layer on the substrate. For example, one fabrication step involves depositing a conductive filler layer on a patterned insulative layer to fill the trenches or holes in the insulative layer. The filler layer is then polished until the raised pattern of the insulative layer is exposed. After planarization, the portions of the conductive filler layer remaining between the raised pattern of the insulative layer form vias, plugs and lines that provide conductive paths between thin film circuits on the substrate.

Chemical mechanical polishing (CMP) is one accepted method of planarization. This planarization method typically requires that the substrate be mounted on a carrier head. The exposed surface of the substrate is placed against a rotating polishing pad. The carrier head provides a controllable load on the substrate to push it against the polishing pad. A polishing liquid, such as slurry with abrasive particles, is supplied to the surface of the polishing pad.

One problem in CMP is determining whether the polishing process is complete, i.e., whether a substrate layer has been planarized to a desired flatness or thickness, or when a desired amount of material has been removed. Variations in the slurry composition, the polishing pad condition, the relative speed between the polishing pad and the substrate, the initial thickness of the substrate layer, and the load on the substrate can cause variations in the material removal rate. These variations cause variations in the time needed to reach the polishing endpoint. Therefore, determining the polishing endpoint merely as a function of polishing time can lead to non-uniformity within a wafer or from wafer to wafer.

In some systems, a substrate is monitored in-situ during polishing, e.g., through the polishing pad. One monitoring technique is to induce an eddy current in the conductive layer and detect the change in the eddy current as the conductive layer is removed.

### SUMMARY

In one aspect, a method of chemical mechanical polishing includes placing a backside conductive layer of a substrate in contact with a polishing surface, where the substrate include a semiconductor wafer, transistors formed in a front-side surface of the semiconductor wafer, a front-side conductive layer formed on the front-side of the semiconductor wafer, and conductive vias extending through the semiconductor wafer to electrically connect the backside conductive layer to the front-side conductive layer. During polishing of the backside conductive layer, a sensor of an in-situ eddy current monitoring system is repeatedly swept across the substrate so that each respective sweep of the sensor generates a respective signal trace that includes a sequence of signal values, wherein the sensor generates a magnetic field that at least intermittently impinges the substrate. For each respective signal trace, the sequence of signal values is converted to a corresponding thickness trace that includes sequence of thickness values for different locations on the substrate, thus generating a sequence of thickness traces. For each respective thickness trace in the sequence of thickness traces, a plurality of minima in the respective thickness trace are identified. A sequence of layer thickness values over time is calculated based on the plurality of minima from the respective traces in the sequence of thickness traces, and a polishing endpoint is detected or a polishing parameter that affects the polishing process is adjusted based on the sequence of layer thickness values.

In another aspect, rather than a backside conductive layer, the method of chemical mechanical polishing includes placing a conductive layer on packaging of an integrated circuit chip in contact with a polishing surface, where the integrated circuit chip includes a substrate that includes a semiconductor wafer, transistors formed in a front-side surface of the semiconductor wafer, a front-side conductive layer formed on the front-side of the semiconductor wafer, and electrical connections between the conductive layer on the packaging and the front-side conductive layer.

In another aspect, a non-transitory computer readable medium has encoded therein a computer program. The computer program comprises instructions to cause one or more computers to. during polishing, receive a series of signal traces from an in-situ eddy current monitoring system, wherein each signal trace corresponds to a sweep of a sensor of the eddy current monitoring system across a substrate and includes a sequence of signal values. For each respective signal trace, the sequence of signal values is converted to a corresponding thickness trace that includes sequence of thickness values for different locations on the substrate, thus generating a sequence of thickness traces. For each respective thickness trace in the sequence of thickness traces, a plurality of minima in the respective thickness trace are identified. A sequence of layer thickness values over time are calculated based on the plurality of minima from the respective traces in the sequence of thickness traces, and a polishing endpoint is detected or a polishing parameter that affects the polishing process is adjusted based on the sequence of layer thickness values.

In another aspect, an apparatus for chemical mechanical polishing includes a platen having a surface to support a polishing pad, a carrier head to hold a substrate such that a layer on the substrate contacts the polishing pad, an eddy current monitoring system, and a controller. The eddy current monitoring system includes a first plurality of eddy current sensors supported by the platen and arranged in a first ring at a first distance from an axis of rotation of the platen and a second plurality of eddy current sensors supported by the platen and arranged in a second ring at a larger second distance from the axis of rotation of the platen such that each sensor of the first and second pluralities of sensors intermittently sweep below the substrate held by the carrier head and such that each respective sweep of a sensor generates a respective signal trace that includes a sequence of signal values. Each respective sensor is configured to generate a magnetic field that intermittently impinges the substrate. The controller is configured to receive each respective signal trace from the first and second pluralities of sensors, for each respective signal trace convert the sequence of signal values to a corresponding thickness trace that includes sequence of thickness values for different locations on the substrate thus generating a sequence of thickness traces, for each respective thickness trace in the sequence of thickness traces identify a plurality of minima in the respective thickness trace, calculate a sequence of layer thickness values over time based on the plurality of minima from the respective traces in the sequence of thickness traces, and at least one of detect a polishing endpoint or adjust a polishing parameter that affects the polishing process based on the sequence of layer thickness values.

In another aspect, an apparatus for chemical mechanical polishing includes a platen having a surface to support a polishing pad, a carrier head to hold a substrate such that a layer on the substrate contacts the polishing pad, an eddy current monitoring system. The eddy current monitoring system includes a first plurality of eddy current sensors supported by the platen and arranged in a first ring at a first distance from an axis of rotation of the platen and a second plurality of eddy current sensors supported by the platen and arranged in a second ring at a larger second distance from the axis of rotation of the platen such that each sensor of the first and second pluralities of sensors intermittently sweep below the substrate held by the carrier head and such that each respective sweep of a sensor generates a respective signal trace that includes a sequence of signal values. Each respective sensor is configured to generate a magnetic field that intermittently impinges the substrate. A number of sensors in the second plurality of sensors is exactly two or three times a number of sensors in the first plurality of sensors.

In another aspect, an apparatus for chemical mechanical polishing includes a platen having a surface to support a polishing pad, a carrier head to hold a substrate such that a layer on the substrate contacts the polishing pad, an actuator that controls a radial position of the carrier head over the platen, an eddy current monitoring system, and a controller. The eddy current monitoring system includes a first plurality of eddy current sensors supported by the platen and arranged in a first ring at a first distance from an axis of rotation of the platen and a second plurality of eddy current sensors supported by the platen and arranged in a second ring at a larger second distance from the axis of rotation of the platen such that each sensor of the first and second pluralities of sensors intermittently sweep below the substrate held by the carrier head and each respective sweep of a sensor generates a respective signal trace that includes a sequence of signal values. Each respective sensor is configured to generate a magnetic field that intermittently impinges the substrate. The controller is configured to control the actuator such that the second plurality of sensors sweep only across an edge portion of the substrate held by the carrier head, receive each respective signal trace from the first and second pluralities of sensors, for each respective signal trace convert the sequence of signal values to a corresponding thickness trace that includes sequence of thickness values for different locations on the substrate, thus generating a sequence of thickness traces, and at least one of detect a polishing endpoint or adjust a polishing parameter that affects the polishing process based on the sequence of thickness traces.

Certain implementations can optionally include, but are not limited to, one or more of the following advantages. The thickness of a layer of conductive material, particularly a conductive layer on a backside of an integrated circuit or on packaging, can be determined more reliably. The effect of underlayer signals on thickness measurements of a layer being polished can be reduced. Within-wafer non-uniformity (WIWNU) can be reduced, and polishing can be halted more reliably. Thus, the overall fabrication process can have improved yield. The technique does not require a library of reference signals, can be less dependent on notch position of the substrate, and can be less dependent on through-wafer via density.

The details of one or more implementations are set forth in the accompanying drawings and the description below. Other aspects, features and advantages will be apparent from the description and drawings, and from the claims.

### BRIEF DESCRIPTION OF DRAWINGS

FIG. 1 is a schematic side view, partially cross-sectional, of a chemical mechanical polishing station that includes an inductive monitoring system.

FIG. 2 is a schematic circuit diagram of portions of the inductive monitoring system.

FIG. 3 is a schematic top view of a platen of a chemical mechanical polishing station.

FIG. 4 is a schematic cross-sectional view of a substrate having a backside conductive layer.

FIG. 5 is a flowchart illustrating a method of signal processing to generate a thickness trace.

FIG. 6 is a schematic graph of a correlation curve that relates the thickness of a conductive layer being polished to the signal.

FIG. 7A illustrates a thickness trace from an eddy current monitoring system from near the start of a polishing process.

FIG. 7B illustrates a thickness trace from an eddy current monitoring system from near the end of a polishing process.

FIG. 8 illustrates a corrected thickness trace generated by selecting minima values from the initial thickness trace.

FIG. 9 is a schematic top view of a platen with multiple sensors.

FIG. 10 illustrates a sequence of values generated by the inductive monitoring system.

FIG. 11 illustrates two sequence of values generated by the inductive monitoring system for two zones on a substrate.

Like reference symbols in the various drawings indicate like elements.

### DETAILED DESCRIPTION

CMP systems can use an eddy-current monitoring system to detect the thickness of a layer of conductive material being polished on a substrate. The measurements can be used to halt polishing when the layer reaches a target thickness or when a patterned underlying layer is exposed, or to adjust processing parameters of the polishing process in real time to improve layer thickness uniformity.

An eddy current monitoring system can be subject to signal distortion due to “noise” originating from underlying layers. For example, underlying metal layers with high conductivity can generate unwanted contribution to the signal from the eddy current sensor, which interferes with the monitoring of the conductive layer of primary interest. For some integrated circuit fabrication steps, e.g., during polishing of the front-side of the substrate, the underlying conductive layers are patterned, e.g., to form vias and lines. Such small features are not particularly conducive to the generation of eddy currents, so the distortion generated by the underlying layers can be managed, e.g., by subtracting out a background trace from the thickness trace generated during polishing.

However, newer generations of integrated circuit chips have begun to use conductive wiring on the backside of the substrate, as well as on the integrated circuit packaging itself. As an example, some integrated circuit chips can include a backside power delivery network (BSPDN), which includes conductive wiring formed on the backside of the wafer and conductive vias through the substrate to deliver power to the circuits on the front-side of the wafer. As such, the backside circuitry is coupled to the circuitry on the front-side of the substrate. Similarly, conductive wiring on the chip packaging is coupled to both the backside and front-side circuitry.

As a result, eddy current monitoring of polishing of a conductive layer on the backside of the substrate or on the chip packaging can be subject to significantly higher noise, as well as noise that cannot be removed due to subtraction of a background signal. Without being limited to any particular theory, the first problem might result from the sensor passing over vias where there are electrical connections to the front-side conductive layers, resulting in spikes in the signal strength. And again without being limited to any particular theory, the second problem might result from the signal contribution of the conductive layers on the front-side of the substrate being convoluted with the contribution of the conductive layer on the backside of the substrate such that the contribution changes as the backside metal layer is being polished.

A technique that could address these issues is to monitor the “valleys”, i.e., minima, in the signal or thickness traces from the eddy current monitoring system. For example, individual minima in a thickness trace can be identified. If there is negligible contribution to the signal from the environmental background (e.g., from the slurry, or from metal parts in the carrier head), these thickness minima values can be used as the thickness values for the corresponding positions of the measurement on the substrate. If the environmental does contribute to the signal, then an environment background trace can be measured during system setup and the environment background trace can be subtracted from the thickness trace to generate a corrected thickness trace, and minima can be identified in the corrected thickness trace.

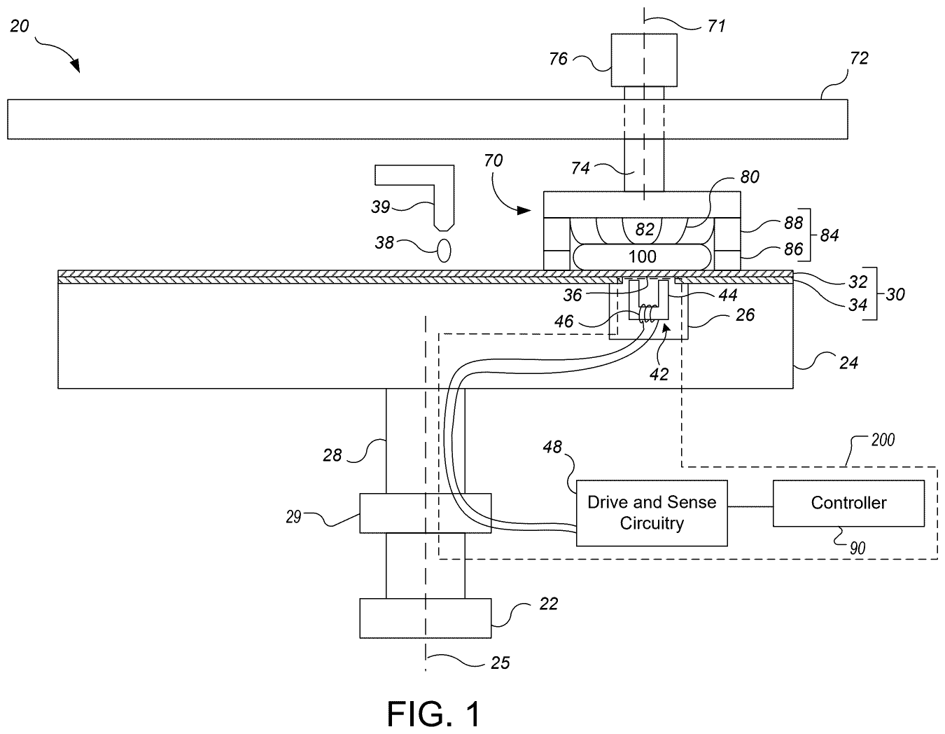

FIG. 1 illustrates an example of a polishing station 20 of a chemical mechanical polishing apparatus. The polishing station 20 includes a rotatable disk-shaped platen 24 on which a polishing pad 30 is situated. The platen 24 is operable to rotate about an axis 25. For example, a motor 22 can turn a drive shaft 28 to rotate the platen 24. The polishing pad 30 can be a two-layer polishing pad with an outer layer 34 and a softer backing layer 32.

The polishing station 22 can include a supply port or a combined supply-rinse arm 39 to dispense a polishing liquid 38, such as slurry, onto the polishing pad 30. The polishing station 22 can include a pad conditioner apparatus with a conditioning disk to maintain the condition of the polishing pad.

The carrier head 70 is operable to hold a substrate 100 against the polishing pad 30. The carrier head 70 is suspended from a support structure 72, e.g., a carousel or a track, and is connected by a drive shaft 74 to a carrier head rotation motor 76 so that the carrier head can rotate about an axis 71. Optionally, the carrier head 70 can oscillate laterally, e.g., on sliders on the carousel, by motion along the track, or by rotational oscillation of the carousel itself. In operation, the platen is rotated about its central axis 25, and the carrier head is rotated about its central axis 71 and translated laterally across the top surface of the polishing pad 30. Where there are multiple carrier heads, each carrier head 70 can have independent control of its polishing parameters, for example each carrier head can independently control the pressure applied to each respective substrate.

The carrier head 70 can include a flexible membrane 80 having a substrate mounting surface to contact the back side of the substrate 100, and a plurality of pressurizable chambers 82 to apply different pressures to different zones, e.g., different radial zones, on the substrate 100. The carrier head can also include a retaining ring 84 to hold the substrate. In some implementations, the retaining ring 84 may include a highly conductive portion, e.g., the carrier ring can include a thin lower plastic portion 86 that contacts the polishing pad, and a thick upper conductive portion 88.

A recess 26 is formed in the platen 24, and optionally a thin section 36 can be formed in the polishing pad 30 overlying the recess 26. The recess 26 and thin pad section 36 can be positioned such that regardless of the translational position of the carrier head they pass beneath substrate 10 during a portion of the platen rotation. Assuming that the polishing pad 30 is a two-layer pad, the thin pad section 36 can be constructed by removing a portion of the backing layer 32. The thin section can optionally be optically transmissive, e.g., if an in-situ optical monitoring system is integrated into the platen 24.

An in-situ eddy current monitoring system 40 generates a time-varying sequence of values that depend on the thickness of the conductive layer being polished on the substrate 100. In operation, the polishing station 22 uses the monitoring system 40 to determine when the conductive layer has been polished to a target thickness or if the underlying patterned dielectric layer has been exposed.

The eddy current monitoring system 40 can include an eddy current sensor 42 installed in the recess 26 in the platen. The sensor 26 can include a magnetic core 44 positioned at least partially in the recess 26, and at least one coil 46 wound around the core 44. Drive and sense circuitry 48 is electrically connected to the coil 46. The drive and sense circuitry 48 generates a signal that can be sent to a controller 90. Although illustrated as outside the platen 24, some or all of the drive and sense circuitry 48 can be installed in the platen 24. A rotary coupler 29 can be used to electrically connect components in the rotatable platen, e.g., the coil 46, to components outside the platen, e.g., the drive and sense circuitry 48.

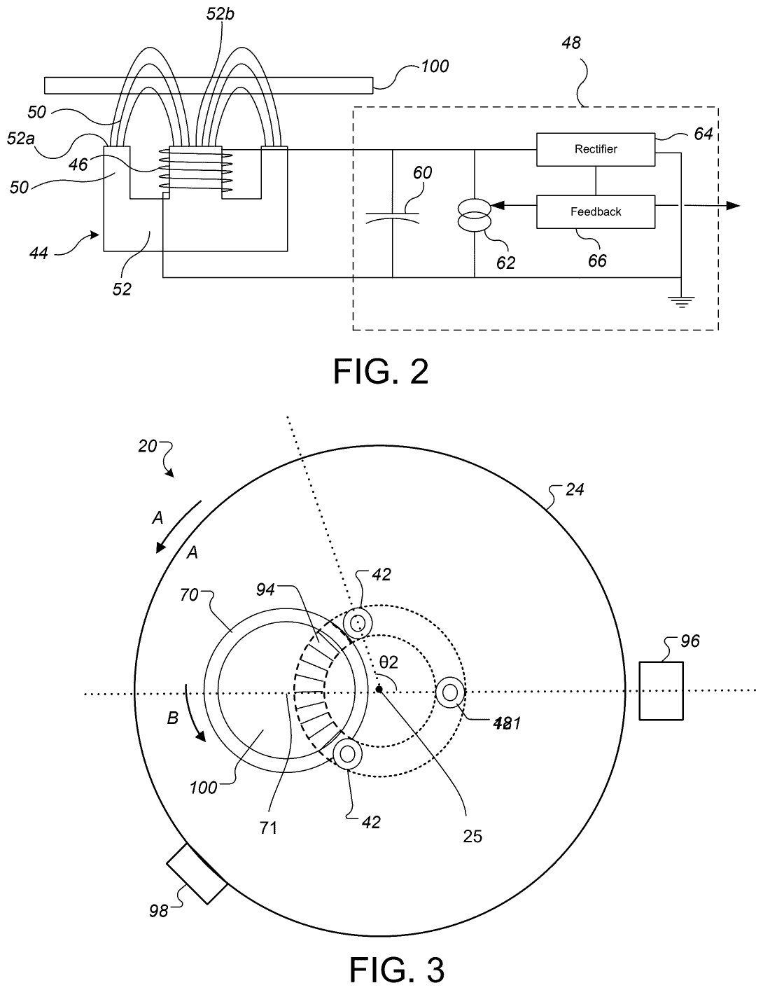

The core 44 can include two (see FIG. 1) or three (see FIG. 2) prongs 50 extending in parallel from a back portion 52. Implementations with only one prong (and no back portion) are also possible.

Referring to FIG. 2, in operation the drive and sense circuitry 48 drives the coil 46 with an AC current to generate an oscillating magnetic field 50 between the poles 52a and 52b of the core 44. At least a portion of magnetic field 50 extends through the polishing pad 30 and into substrate 100. If a conductive layer is present on substrate 100, the oscillating magnetic field 40 generates eddy currents in the conductive layer. The eddy currents cause the conductive layer to act as an impedance source that is coupled to the drive and sense circuitry 48. As the thickness of the conductive layer changes, the impedance changes, resulting in a change in the output signal from the drive and sense circuitry 48.

FIG. 2 illustrates an example of the drive and sense circuitry 48. The circuitry 48 includes a capacitor 60 connected in parallel with the coil 46. Together the coil 46 and the capacitor 60 can form an LC resonant tank. In operation, a current generator 62 (e.g., a current generator based on a marginal oscillator circuit) drives the system at the resonant frequency of the LC tank circuit formed by the coil 46 (with inductance L) and the capacitor 60 (with capacitance C). The current generator 62 can be designed to maintain the peak to peak amplitude of the sinusoidal oscillation at a constant value. A time-dependent voltage with amplitude V₀ is rectified using a rectifier 64 and provided to a feedback circuit 66. The feedback circuit 66 determines a drive current for current generator 62 to keep the amplitude of the voltage V₀ constant. Marginal oscillator circuits and feedback circuits are further described in U.S. Pat. Nos. 4,000,458, and 7,112,960.

Other configurations are possible for the drive and sense circuitry 48. For example, separate drive and sense coils could be wound around the core, the drive coil could be driven at a constant frequency, and the amplitude or phase (relative to the driving oscillator) of the current from the sense coil could be used for the signal.

FIG. 3 illustrates a top view of the platen 24. As the platen 24 rotates (as shown by arrow A), the sensor 42 sweeps below the substrate 100. Sampling the signal from the circuitry 48 at a sampling frequency generates a sequence of measurements, e.g., a sequence of signal values, at a sequence of sampling zones 94 across the substrate 100. In some implementations, multiple sensors 42 are installed in the platen 24 so as to increase the sweep frequency.

The polishing station 20 can also include a position sensor 96, such as an optical interrupter, to sense when the inductive sensor 42 is underneath the substrate 100 and when the eddy current sensor 42 is off the substrate. For example, the position sensor 96 can be mounted at a fixed location opposite the carrier head 70. A flag 98 can be attached to the periphery of the platen 24. The point of attachment and length of the flag 98 is selected so that it can signal the position sensor 96 when the sensor 42 sweeps underneath the substrate 100.

Alternately, the polishing station 20 can include an encoder to determine the angular position of the platen 24. The inductive sensor can sweep underneath the substrate with each rotation of the platen.

Returning to FIG. 1, a controller 90, e.g., a general purpose programmable digital computer, receives the sequence of signal values (this functionality of the controller 90 can be considered part of the eddy current monitoring system). Since the sensor 42 sweeps beneath the substrate 100 with each rotation of the platen 24, information on the thickness of the conductive layer on the substrate 100 is accumulated in-situ and on a continuous real-time basis (once per sensor per platen rotation). The controller 90 can be programmed to sample measurements from the monitoring system when the sensor(s) 42 passes below the substrate 100 (as determined by the position sensor). In addition, off-wafer measurements may be performed at the locations where the sensor 49 is not positioned under the substrate 10. The measurements from the monitoring system can be displayed on an output device during polishing to permit the operator of the device to visually monitor the progress of the polishing operation, although this is not required.

The controller 90 may also be connected to the pressure mechanisms that control the pressure applied by carrier head 70, to carrier head rotation motor 76 to control the carrier head rotation rate, to the platen rotation motor 21 to control the platen rotation rate, or to slurry distribution system 39 to control the slurry composition supplied to the polishing pad.

Assuming the thickness of the layer varies across the substrate, the change in the position of the sensor head with respect to the substrate 10 can result in a change in the signal from the in-situ eddy current monitoring system 40. The sequence of signal values resulting from a single sweep of a single sensor below the substrate may be referred to as a signal trace. Variation in the signal across a signal trace can indicate variation in the layer thickness across the substrate. In addition, as polishing progresses, the thickness of the conductive layer changes. So trace-to-trace differences can indicate variation in the layer thickness over time. Where multiple sensors 42 are installed in the platen 24, multiple traces will be generated per rotation of the platen 24 (so the sweep frequency will be an integer multiple of the platen rotation rate).

The controller 90 can be programmed to calculate the radial position relative to the axis of rotation 71 of the carrier head of each measurement, e.g., each signal value, from the eddy current monitoring system 40. Calculation of radial positions is discussed in U.S. Pat. No. 6,399,501.

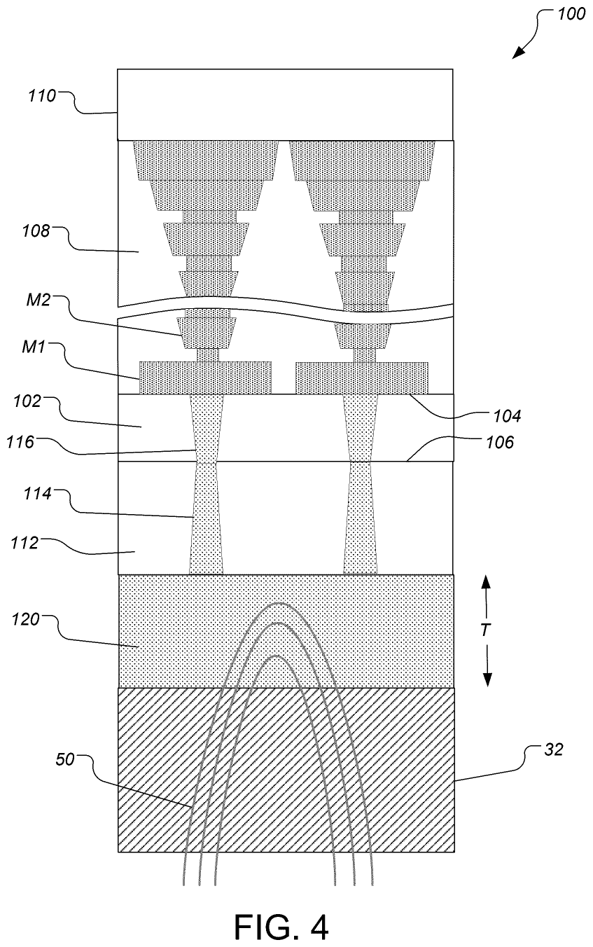

FIG. 4 illustrates an example of a substrate 100 that can be polished at the polishing station 20. In this example, the substrate 100 has backside conductive layer 120 being polished by the polishing layer 32 of the polishing pad. For example, the substrate 100 could be a device substrate being processed during fabrication of an integrated circuit chip that will include a backside power delivery network (BSPDN). The substrate includes a semiconductor wafer 102, e.g., a silicon wafer, having a frontside surface 104 on which transistors are formed, and a backside surface 106. Multiple dielectric and metal layers 108 can be formed on the frontside surface. The metal layers are sometimes referred to as M1, M2, etc., with M1 being the metal layer closest to the semiconductor wafer. In some substrates, a second semiconductor wafer 110 can be attached to the top of the stack of metal layers 108.

On the backside of the wafer 102 substrate is a dielectric layer 112, and conductive vias 114, 116 are formed through the dielectric layer 112 and wafer 102 to electrically couple the backside conductive layer 120 to the circuitry on the frontside of the wafer 102, e.g. to the metal layers 108.

When such a substrate is being polished and monitored with the eddy current monitoring system, the magnetic field 50 generated by the sensor can extend through the polishing layer 32 of the polishing pad 30 and into the backside conductive layer 120 (the field lines of the magnetic field 50 are shown extending only into the backside conductive layer 120 in FIG. 4 only for ease of illustrate; in practice the field lines might extend entirely through the substrate). However, due to the presence of the conductive vias 114, 116, current induced by the magnetic field 50 in the front side conductive layers 108 can interact with the current induced in the backside conductive layer 120. As a result, contribution due to the thickness T1 of the backside conductive layer 120 to the signal becomes convoluted with the contribution of the front-side layers 108 to the signal and with the density of the conductive vias 114, 116.

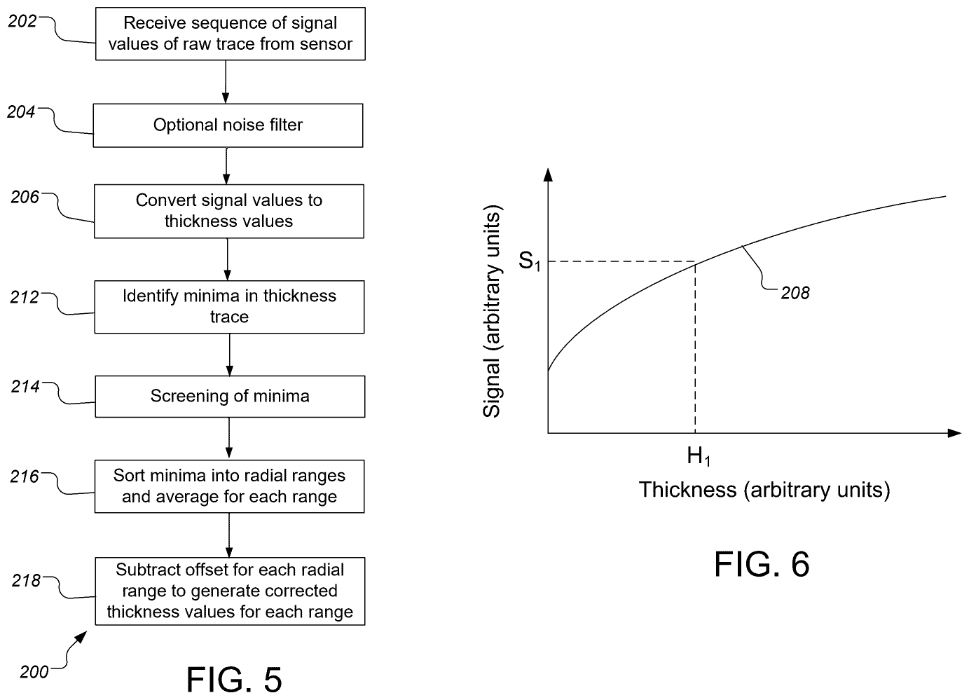

Returning to FIG. 1, the signal from the drive and sense circuitry 48 is raw data, e.g., a sequence of voltage values. Thus, this raw data needs to be converted into thickness values. FIG. 5 illustrates a method 200 to generate a thickness trace, i.e., a sequence of thickness values representing thicknesses of the layer at different positions across the substrate, from the signal trace. This method can compensate for contributions from underlying layers, e.g., from front-side layers during polishing of a backside conductive layer.

Referring to FIGS. 1 and 5, the controller 90 receives (202) the sequence of signal values of a signal trace, e.g., from the drive and sense circuitry 48. Optionally, the signal trace is filtered to remove noise (204). For example, a smoothing or low-pass filter can be applied to the signal trace to remove very high frequency noise. However, care should be taken in selection of the filter parameters so that the peaks and valleys resulting from the sensor passing over vias are not removed. In some implementations, it may not be necessary to apply any filter to the signal trace.

Next, the signal values can be converted to thickness values (206). For example, the controller can use a correlation curve that relates the signal measured by the in-situ eddy current monitoring system to the thickness of the layer being polished on the substrate to generate an estimated measure of the thickness of the layer being polished. An example of a correlation curve 208 is shown in FIG. 6. In the coordinate system depicted in FIG. 6, the horizontal axis represents the value of the signal received from the in-situ eddy current monitoring system, whereas the vertical axis represents the value for the thickness of the layer of the substrate 10. For a given signal value, the controller can use the correlation curve 208 to generate a corresponding thickness value. Consequently, the sequence of signal values in a signal trace is converted to a sequence of thickness values in a thickness trace. The correlation curve 208 can be considered a “static” formula, in that it predicts a thickness value for each signal value regardless of the time or position at which the sensor head obtained the signal. The correlation curve can be represented by a variety of functions, such as a polynomial function, or a look-up table (LUT) combined with linear interpolation.

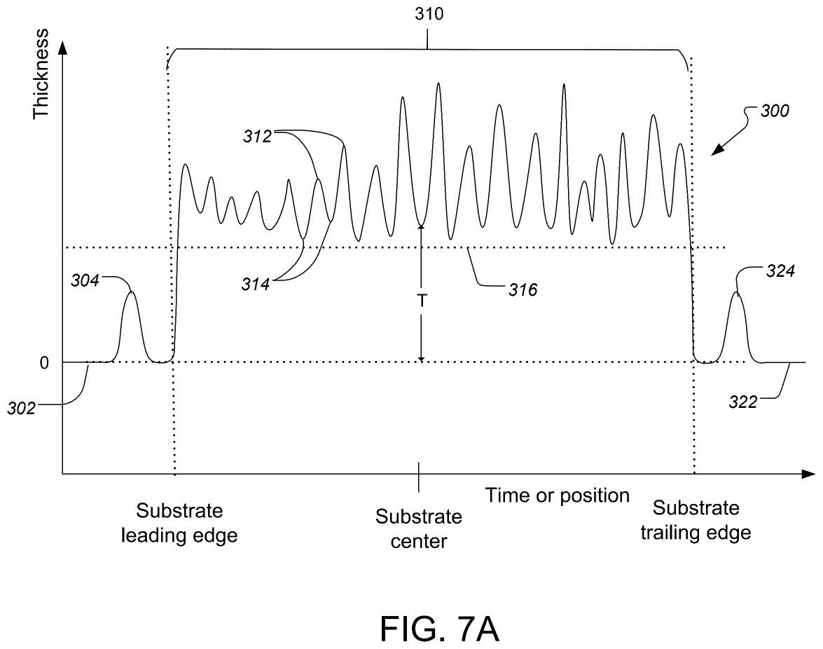

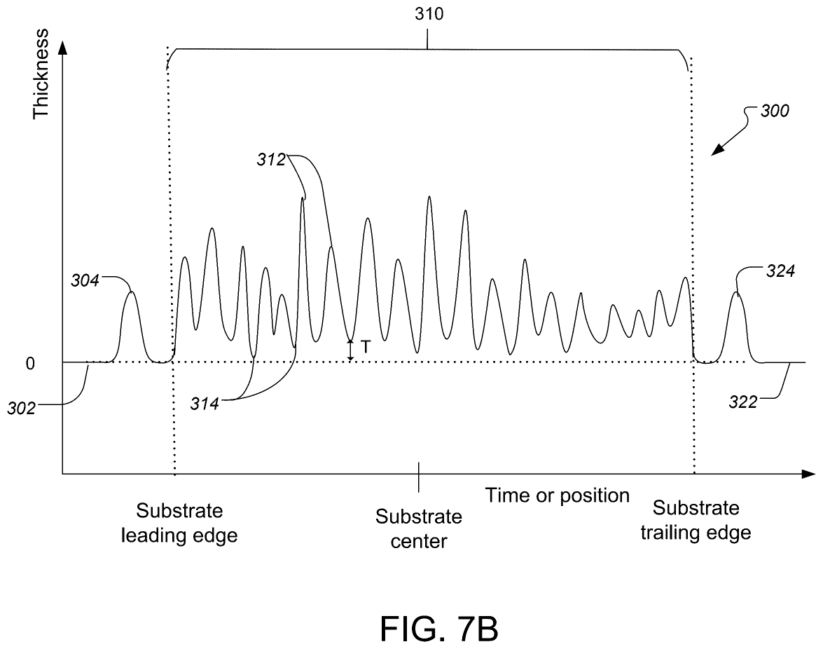

FIGS. 7A and 7B illustrate graphs of thickness traces 300, each from a single sweep of the sensor 42 across a substrate 100. The thickness trace 300 in FIG. 7A can be generated from a sweep near the beginning of a polishing process for a substrate, whereas the thickness trace 300 in FIG. 7B can be generated from a sweep near the end of the polishing process, e.g., near the polishing endpoint. Although illustrated as a continuous curve, as previously discussed each thickness trace 300 would actually be a sequence of individual thickness values. In the graph, the horizontal axis represents the distance from the center of the substrate, and the vertical axis represents the thickness (e.g., in Angstroms).

The thickness trace 300 includes an initial flat portion 302 of low signal strength. The portion 302 can represent measurements when the sensor is not below the carrier head, so there is nothing to generate a signal. This is followed by a “bump” 304 of moderate signal strength. This portion 134 can represent measurements while the sensor 42 passes below the retaining ring 84, so metal parts in the carrier or retaining ring might generate some signal.

There then follows a portion 310 that appears to have significant “noise”, with many individual maxima 312 and minima 314. The portion 310 can begin with a sharp increase in the signal strength, indicating when the sensor passes over the leading edge of the substrate, and end at a sharp decrease in the signal strength, indicating when the sensor passes over the trailing edge of the substrate.

In general, over the portion 310, the signal strength does not fall below a minimum level 316. Without being limited to any particular theory, the maxima 312 can represent measurements when the sensor 42 is located below a region of the substrate in which the signal has a strong contribution from the “underlayers.” For example, when polishing a backside conductive layer, this may be where vias connect the backside conductive layer to the front-side conductive layers, e.g., M1, M2, etc. In contrast, each minima 314 can represent a measurement when the sensor 42 is located below a region of the substrate in which the signal has a minimal contribution from the “underlayers.” As such, the minima 314 should represent a more accurate indication of the thickness of the conductive layer being polished. One of these thickness values is indicated by difference T.

The portion 310 of the signal corresponding to the sensor passing below the substrate 100 is followed by another “bump” 324 corresponding to the sensor 42 passing below the retaining ring 84 on the farther side of the substrate 100, and then a final flat portion 322 of low signal strength that corresponds to the sensor 42 once again not being below the carrier head.

As shown by FIG. 7B, as the polishing process progresses, the “noisy” portion 310, and in particular the minimum level 316 and the individual minima 314, can shift downward over time. Assuming endpoint is to occur when an underlying layer has been exposed, e.g., the dielectric layer 112 is exposed leaving conductive material in the vias 114, the minimum level 316 will gradually approach zero thickness.

Referring to FIGS. 5 and 7A-7B, individual minima 314 in the thickness trace 300 are identified by the controller 90 (212). For example, the controller 90 can calculate a second derivative of the sequence of thickness values and then identify locations in the second derivative signal that are above a threshold value.

In some implementations, not all of the minima 314 are used. A screening step (214) can remove some of the minima. For example, the controller 90 can be set to discard a preset percentage, e.g., 5-30%, e.g., 20%, of the minima having the highest thickness values. Alternatively, the controller 90 can be set to discard thickness values above a preset threshold.’

If the polishing environment contributes to the signal, e.g., due to the presence of slurry or conductive parts in the carrier head, then an environment background trace can be measured during system setup. The environment background trace can be subtracted from an initial thickness trace to generate the thickness trace.

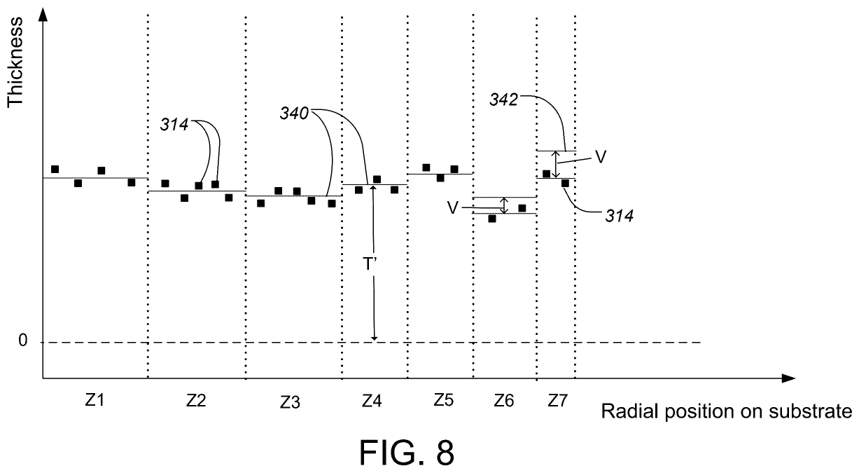

Referring to FIGS. 5 and 8, the controller 90 can also be programmed to sort the thickness values 314 from the thickness trace 300 into radial ranges based on the radial position of the corresponding measurement. Although FIG. 8 illustrates seven radial ranges Z1-Z7, there could be two to six, or eight or more radial ranges. Each respective radial range can correspond to an area on the substrate controlled by one of the respective pressurizable chambers in the carrier head 70.

In some implementations, thickness values 314 for measurements within each respective radial range are combined, e.g., averaged, to generate a thickness value 340 (illustrated by the horizontal line across the radial range) for that respective radial range (316). One of these thickness values is indicated by T′.

After sorting the thickness values into radial ranges and generating an average value for each radial range, information on the film thickness for each radial range can be fed in real-time into a closed-loop controller to periodically or continuously modify the polishing pressure profile applied by a carrier head in order to provide improved polishing uniformity.

Still referring to FIGS. 5 and 8, in some implementations, for each of one or more of the radial ranges Z1-Z7, a respective offset value V is added to the thickness value of that radial range to generate a corrected thickness value for that radial range. The offset value for each radial range can be different from the offset value(s) for the other radial range(s).

In some implementations, the offset value is used only for the outermost radial range, i.e., the radial range closest to the substrate edge. In some implementations, offset values are used for the two or three outermost radial ranges. In particular, signal values generated when the measurement region of the sensor overlaps the substrate edge can be distorted, e.g., artificially low. This distortion in the signal can cause errors in the calculation of the layer thickness near the substrate edge. Thus, an offset to the measured values can be used to address this problem.

The offset value(s) can be empirically determined, and can be generated from the difference between a ground truth measurement of a layer thickness and the thickness output of the in-situ monitoring system for the layer thickness. For example, if the in-situ monitoring system indicates a layer thickness of 200 Å for a radial range, e.g., the outermost radial range, whereas a measurement by a four-point probe indicates a layer thickness of 300 Å for that radial range, the difference of 100 Å can be stored as an offset. Then in operation, the 100 Å offset is added to the thickness value for the appropriate radial range. Alternatively, the offset can be subtracted from the target thickness of an endpoint detection or closed loop control system (instead of being added to the measured thickness).

A potential issue is that by selecting the minima thickness measurements from the initial thickness trace 310, there may be only a limited number of thickness values 314 for certain areas of the substrate, particularly for the radial regions closer to the edge of the substrate. This can render the thickness measurement for these radial regions to be less reliable.

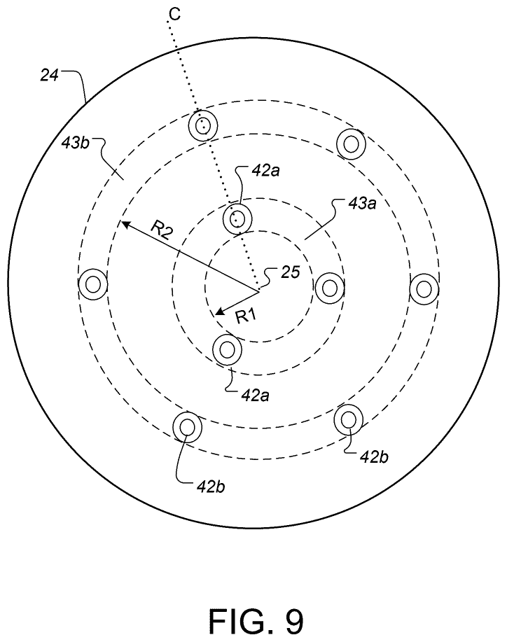

Referring to FIG. 9, to address this problem multiple sensors 42 can be installed in the platen 24 in order to increase the number of measurements of the substrate obtained per rotation of the platen 24. In particular, at least some of the sensors 42 can be positioned at a location where they are likely to sweep across the edge region of the substrate. The edge region of the substrate can be the outer 15%, e.g., the outer 10%, of the radius of the substrate. This can increase the number of thickness measurement for the radial regions closer to the substrate edge, e.g., the outermost radial region (Z7), or the two or three outermost radial regions (Z6-Z7 or Z5-Z7).

The implementation illustrated in FIG. 9 includes a first plurality of sensors 42a arranged in a first ring 43a at a first radial distance R1 from the axis of rotation 25 of the platen 24, and a second plurality of sensors 42b arranged in a second ring 43b at a second radial distance R2 from the axis of rotation 25 of the platen 24. The number of sensors 42b in the second ring 43b may be two or three times larger than the number of sensors 42a in the first ring 43a. Some of the sensors 42b in the second ring 43b, e.g., every other sensor 42b, can be aligned at a common angular position (as shown by the phantom line C). In some implementations, the first plurality of sensors 42a may be 7-8 inches from the axis of rotation 25, whereas the second plurality of sensors 42a may be 2.5-4 inches from the axis of rotation 25.

In some implementations, the controller 90 sets the oscillation of the carrier head 70 across the platen 24 such that the second plurality of sensors 42b in the second ring 43b sweep only under the edge region of the substrate.

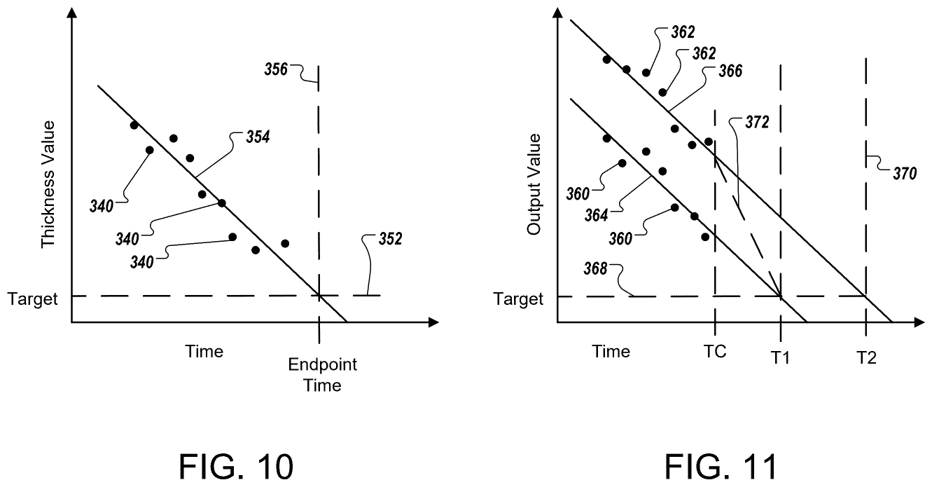

FIG. 10 is an example graph of the output values 340, e.g., the average thickness values, generated by the eddy current monitoring system 40 during polishing of a device substrate 100, for a single radial region on the substrate. In the graph, the horizontal axis represents time and the vertical axis represents the thickness value.

In some implementations, a function 354 is fit to the sequence of output values 340, e.g., using a robust line fit. The function 354 can be used to determine the polishing endpoint time 356. In some implementations, the function 354 is a linear function of time. In some implementations, the time at which the function 354 equals a target value 352, provides the endpoint time 356.

FIG. 11 is an example graph of output values for two different zones on the substrate 100. For example, the controller 90 can track a first zone at or near a center of the substrate 100 and a second zone located toward an edge of the substrate 100. A sequence of first output values 360, e.g., the thickness values 340 from a first radial range, e.g., Z1, can be generated for the first zone of the substrate 100, and a sequence of second output values 362, e.g., the thickness values 340 from a second radial range, e.g., Z7, can similarly be generated for the second zone of the substrate 100. Each radial range can correspond to the radial range on the substrate to which the applied pressure is controlled by pressurization of a respective chamber 82 in the carrier head 70.

A first function 362, e.g., a first line, can be fit to the sequence of first output values 364, and a second function 366, e.g., a second line, can be fit to the sequence of second values 362. The first function 364 and the second function 366 can be used to determine to an adjustment to the polishing rate of the substrate 100.

During polishing, estimated endpoint calculations based on a target value 368 are made at time TC with the first function for the first zone of the substrate 100 and with the second function for the second zone of the substrate 100. The target value 368 represents the output of the inductive monitoring system when the trench has a target depth. If the estimated endpoint times T1 and T2 for the first and the second zones differ (or if the values of the first function and second function at an estimated endpoint time 370 differ), the polishing rate of at least one of the zones can be adjusted so that the first zone and second zone have closer to the same endpoint time than without such an adjustment. For example, if the first zone will reach the target value 368 before the second zone, the polishing rate of the second zone can be increased (shown by line 372) such that the second zone will reach the target value 368 at substantially the same time as the second zone. In some implementations, the polishing rates of both the first portion and the second portion of the substrate are adjusted so that endpoint is reached at both portions simultaneously. Alternatively, the polishing rate of only the first portion or the second portion can be adjusted.

The eddy current monitoring system can be used in a variety of polishing systems. Either the polishing pad, or the carrier head, or both can move to provide relative motion between the polishing surface and the substrate. The polishing pad can be a circular (or some other shape) pad secured to the platen, a tape extending between supply and take-up rollers, or a continuous belt. The polishing pad can be affixed on a platen, incrementally advanced over a platen between polishing operations, or driven continuously over the platen during polishing. The pad can be secured to the platen during polishing, or there can be a fluid bearing between the platen and polishing pad during polishing. The polishing pad can be a standard (e.g., polyurethane with or without fillers) rough pad, a soft pad, or a fixed-abrasive pad.

The functional operations described in this specification, e.g., of the controller 90, can be implemented in digital electronic circuitry, or in computer software, firmware, or hardware, including the structural means disclosed in this specification and structural equivalents thereof, or in combinations of them. Embodiments can be implemented as one or more computer program products, i.e., one or more computer programs tangibly embodied in an information carrier, e.g., in a non-transitory machine-readable storage medium or in a propagated signal, for execution by, or to control the operation of, data processing apparatus, e.g., a programmable processor, a computer, or multiple processors or computers. A computer program (also known as a program, software, software application, or code) can be written in any form of programming language, including compiled or interpreted languages, and it can be deployed in any form, including as a stand-alone program or as a module, component, subroutine, or other unit suitable for use in a computing environment. A computer program does not necessarily correspond to a file. A program can be stored in a portion of a file that holds other programs or data, in a single file dedicated to the program in question, or in multiple coordinated files (e.g., files that store one or more modules, sub-programs, or portions of code). A computer program can be deployed to be executed on one computer or on multiple computers at one site or distributed across multiple sites and interconnected by a communication network.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application-specific integrated circuit).

A number of embodiments have been described. Nevertheless, it will be understood that various modifications may be made without departing from the spirit and scope of the invention. Accordingly, other embodiments are within the scope of the following claims.

What is claimed is:

1. A method of chemical mechanical polishing, comprising:
placing a backside conductive layer of a substrate in contact with a polishing surface, wherein the substrate include a semiconductor wafer, transistors formed in a front-side surface of the semiconductor wafer, a front-side conductive layer formed on the front-side of the semiconductor wafer, and conductive vias extending through the semiconductor wafer to electrically connect the backside conductive layer to the front-side conductive layer;
during polishing of the backside conductive layer, repeatedly sweeping a sensor of an in-situ eddy current monitoring system across the substrate so that each respective sweep of the sensor generates a respective signal trace that includes a sequence of signal values, wherein the sensor generates a magnetic field that at least intermittently impinges the substrate;
for each respective signal trace, converting the sequence of signal values to a corresponding thickness trace that includes sequence of thickness values for different locations on the substrate, thus generating a sequence of thickness traces;
for each respective thickness trace in the sequence of thickness traces, identifying a plurality of minima in the respective thickness trace;
calculating a sequence of layer thickness values over time based on the plurality of minima from the respective traces in the sequence of thickness traces;
at least one of detecting a polishing endpoint or adjusting a polishing parameter that affects the polishing process based on the sequence of layer thickness values.

2. The method of claim 1, wherein identifying a plurality of minima in the respective thickness trace includes generating a second derivative of the respective thickness trace.

3. The method of claim 1, wherein identifying a plurality of minima in the respective thickness trace includes identifying each minima in the respective thickness trace and screening out a portion of the multiplicity of minima to provide the plurality of minima.

4. The method of claim 3, wherein screening out a portion of the multiplicity of minima comprises discarding a preset percentage of the minima having the largest thickness values.

5. The method of claim 3, wherein screening out a portion of the multiplicity of minima comprises discarding minima having thickness values above a preset threshold.

6. The method of claim 3, wherein calculating the sequence of layer thickness values comprises, for each sweep, averaging thickness values from a sweep.

7. The method of claim 6, wherein calculating the sequence of layer thickness values comprises calculating a sequence of layer thickness values for each of a plurality of zones on the substrate, and wherein calculating the sequence of layer thickness values for a respective zone from the plurality of zones comprises, for each sweep, averaging thickness values from a sweep for measurements from the respective zone.

8. The method of claim 1, comprising applying a filter to the signal trace to generate a smoothed signal trace.

9. The method of claim 1, wherein converting the sequence of signal values to a corresponding thickness trace comprises using a correlation curve that outputs a thickness as a function of signal.

10. The method of claim 1, comprises subtracting an environmental background trace from an initial thickness trace to generate the thickness trace.

11. A method of chemical mechanical polishing, comprising:
placing a conductive layer on packaging of an integrated circuit chip in contact with a polishing surface, wherein the integrated circuit chip includes a substrate that includes a semiconductor wafer, transistors formed in a front-side surface of the semiconductor wafer, a front-side conductive layer formed on the front-side of the semiconductor wafer, and electrical connections between the conductive layer on the packaging and the front-side conductive layer;
during polishing of the conductive layer on packaging, repeatedly sweeping a sensor of an in-situ eddy current monitoring system across the packaging so that each respective sweep of the sensor generates a respective signal trace that includes a sequence of signal values, wherein the sensor generates a magnetic field that at least intermittently impinges the substrate;
for each respective signal trace, converting the sequence of signal values to a corresponding thickness trace that includes sequence of thickness values for different locations on the substrate, thus generating a sequence of thickness traces;
for each respective thickness trace in the sequence of thickness traces, identifying a plurality of minima in the respective thickness trace;
calculating a sequence of layer thickness values over time based on the plurality of minima from the respective traces in the sequence of thickness traces;
at least one of detecting a polishing endpoint or adjusting a polishing parameter that affects the polishing process based on the sequence of layer thickness values.

12. The method of claim 11, wherein identifying a plurality of minima in the respective thickness trace includes generating a second derivative of the respective thickness trace.

13. The method of claim 11, wherein identifying a plurality of minima in the respective thickness trace includes identifying each minima in the respective thickness trace and screening out a portion of the multiplicity of minima to provide the plurality of minima.

14. The method of claim 13, wherein screening out a portion of the multiplicity of minima comprises discarding a preset percentage of the minima having the largest thickness values.

15. The method of claim 13, wherein screening out a portion of the multiplicity of minima comprises discarding minima having thickness values above a preset threshold.

16. The method of claim 13, wherein calculating the sequence of layer thickness values comprises, for each sweep, averaging thickness values from a sweep.

17. The method of claim 16, wherein calculating the sequence of layer thickness values comprises calculating a sequence of layer thickness values for each of a plurality of zones on the substrate, and wherein calculating the sequence of layer thickness values for a respective zone from the plurality of zones comprises, for each sweep, averaging thickness values from a sweep for measurements from the respective zone.

18. A non-transitory computer readable medium having encoded therein a computer program, the computer program comprising instructions to cause one or more computers to:
during polishing, receive a series of signal traces from an in-situ eddy current monitoring system, wherein each signal trace corresponds to a sweep of a sensor of the eddy current monitoring system across a substrate and includes a sequence of signal values;
for each respective signal trace, convert the sequence of signal values to a corresponding thickness trace that includes sequence of thickness values for different locations on the substrate, thus generating a sequence of thickness traces;
for each respective thickness trace in the sequence of thickness traces, identify a plurality of minima in the respective thickness trace;
calculate a sequence of layer thickness values over time based on the plurality of minima from the respective traces in the sequence of thickness traces; and
at least one of detect a polishing endpoint or adjust a polishing parameter that affects the polishing process based on the sequence of layer thickness values.

19. The computer readable medium of claim 18, wherein the instructions to convert the sequence of signal values to a corresponding thickness trace comprise instructions to subtract an environmental background trace from an initial thickness trace to generate the corresponding thickness trace.

20. The computer readable medium of claim 18, comprising instructions to calculate a sequence of layer thickness values for each respective zone of a plurality of zones by, for each sweep, averaging thickness values from a sweep for measurements from the respective zone.

21. The computer readable medium of claim 20, wherein the instructions to convert the sequence of signal values to a corresponding thickness trace comprise instructions to convert a signal value to an initial thickness value using a correlation curve.

22. The computer readable medium of claim 21, comprising instructions to, for one or more respective zones of the plurality of zones at which the sensor would partially overlap an edge of the substrate, add an offset value to the thickness value for the respective zone to at least partially compensate for signal loss due to the sensor partially overlapping the edge of the substrate.
